(19) United States
(12) Patent Application Publication
(10) Pub. No.: US 2016/0178812 A1
(43) Pub. Date: Jun. 23, 2016

(54) OPTICAL FILM AND DISPLAY ASSEMBLY APPLYING THE SAME

(71) Applicants: Industrial Technology Research Institute, Hsinchu (TW); UNIVERSITY OF CENTRAL FLORIDA RESEARCH FOUNDATION INC, Orlando, FL (US)

(72) Inventors: Ya-Ting Gao, Orlando, FL (US); Zhen-Yue Luo, Orlando, FL (US); Shin-Tson Wu, Orlando, FL (US); Kuo-Chang Lee, Pingtung County (TW); Cheng-Chung Lee, Hsinchu City (TW)

(21) Appl. No.: 14/576,221

(22) Filed: Dec. 19, 2014

(51) Int. Cl. G02B 5/00; H01L 27/32; G02B 5/08

(52) U.S. Cl. CPC G02B 5/003; G02B 5/08; H01L 27/3244; H01L 27/3281

(57) ABSTRACT

An optical film and a display assembly applying the optical film are provided. The optical film may comprise a plurality of truncated tapered units embedded in a material layer for transmitting a light emitted from the display unit by reflecting the light through a reflection surface between the truncated tapered units and the material layer, wherein a ratio of the area of a first end surface where the light emerges from each truncated tapered unit and the area of a second end surface where the light is incident into each truncated tapered may be between 0.2 and 0.6. Furthermore, a light absorbing layer may be formed on a light output side of the optical film for absorbing ambient light.

### TECHNICAL FIELD

The technical field relates to an optical film and a display assembly applying the same.

### BACKGROUND

The current generation is frequently proclaimed as the 3C era: the Computer, the Communication and the Consumer electronics era. In our daily life, we encounter many kinds of information products such as mobile phones, personal digital assistants (PDAs), global positioning satellite (GPS) systems and digital cameras. Most information equipment uses a flat panel display as the main communication medium. For example, liquid crystal displays, plasma displays and organic light emitting diode (OLED) panels are available for selection. The OLED panel not only has higher brightness level, lower power consumption, higher contrast, rapid response and lower driving voltage, but also has the capability to be miniaturized according to the current trend of communication equipment. Therefore, a large number of OLED panel products are developed in recent years.

In the case of OLED panel, a metallic electrode is used to enhance light extraction efficiency. However, in an environment with high ambient brightness, ambient light may enter the OLED panel and is reflected by the metallic electrode with high reflectivity, which reduces visual contrast of the display panel and affects the image quality.

### SUMMARY

According to an embodiment, an optical film comprises a transparent substrate, a material layer, a plurality of truncated tapered units, and a light absorbing layer. The transparent substrate has a carrying surface. The material layer is disposed on the carrying surface of the transparent substrate. The plurality of truncated tapered units is disposed in the material layer, and each of the truncated tapered units has a first end surface nearby the carrying surface and a second end surface away from the carrying face, wherein a ratio of the area of the first end surface and the area of the second end surface may be larger than or equal to 0.2 and less than or equal to 0.6. A reflection surface is formed between each of the truncated tapered units and the material layer to reflect a light which enters the truncated tapered unit through the second end surface, and the light reflected by the reflection surface is adapted to emerge from the truncated tapered unit through the first end surface. In addition, the light absorbing layer is disposed on the carrying surface and located between the transparent substrate and the material layer, wherein the light absorbing layer has a plurality of openings, and a vertical projection of the openings on the carrying surface overlaps a vertical projection of the first end surfaces of the plurality of truncated tapered units on the carrying surface.

According to another embodiment, a display assembly comprises a display unit having a display side, and an optical film disposed on the display side of the display unit. The optical film comprises a transparent substrate, a material layer, a plurality of truncated tapered units, and a light absorbing layer. The transparent substrate has a carrying surface facing the display unit. The material layer is disposed on the carrying surface of the transparent substrate. The plurality of truncated tapered units is disposed in the material layer, and each of the truncated tapered units has a first end surface nearby the carrying surface and a second end surface away from the carrying face, wherein a ratio of the area of the first end surface and the area of the second end surface is larger than or equal to 0.2 and is less than or equal to 0.6. A reflection surface is formed between each of the truncated tapered units and the material layer to reflect a light which is emitted from the display unit and enters the truncated tapered unit through the second end surface, and the light reflected by the reflection surface is adapted to emerge from the truncated tapered unit through the first end surface. The light absorbing layer is disposed on the carrying surface and located between the transparent substrate and the material layer, wherein the light absorbing layer has a plurality of openings, and a vertical projection of the openings on the carrying surface overlaps a vertical projection of the first end surfaces of the plurality of truncated tapered units on the carrying surface.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 illustrates a display assembly applying an optical film according to an embodiment of the present disclosure.

FIG. 2 further shows a partial enlarged view of the display assembly 10 of FIG.

FIG. 3 shows a table illustrating the relationship between the light transmittance and the geometry of the truncated tapered unit.

FIG. 4 shows a table illustrating the relationship between the light reflectance and the geometry of the truncated tapered unit.

FIG. 5 shows a table illustrating light extraction efficiency versus the distance D.

FIG. 6 shows a table illustrating total reflection and effective reflection versus the distance D.

FIG. 7A illustrates a display assembly according to another embodiment of the present disclosure.

FIG. 7B illustrates a display assembly according to another embodiment of the present disclosure.

FIG. 7C illustrates a display assembly according to another embodiment of the present disclosure.

FIG. 8 illustrates a display assembly according to another embodiment of the present disclosure.

FIG. 9 illustrates a display assembly according to another embodiment of the present disclosure.

FIG. 10 illustrates a display assembly according to another embodiment of the present disclosure.

FIG. 11 illustrates an optical film according to another embodiment of the present disclosure.

FIG. 12 and FIG. 13 illustrate different optical films according to other embodiments of the present disclosure.

FIG. 14 illustrates an optical film according to another embodiment of the present disclosure.

FIG. 15 illustrates an optical film according to another embodiment of the present disclosure.

FIG. 16 illustrates an optical film according to another embodiment of the present disclosure.

FIG. 17 illustrates a display assembly according to another embodiment of the present disclosure.

FIG. 18 illustrates a display assembly according to another embodiment of the present disclosure.

### DETAILED DESCRIPTION OF DISCLOSED EMBODIMENTS

Reference will now be made in detail to the present embodiments of the disclosure, examples of which are illustrated in the accompanying drawings. Wherever possible, the same reference numbers are used in the drawings and the description to refer to the same or like parts.

FIG. 1 illustrates a display assembly applying an optical film according to an embodiment of the present disclosure. The display assembly 10 comprises a display unit 100 having a display side 101, and an optical film 200 disposed on the display side 101 of the display unit 100. Herein, the display unit 100 may be a liquid crystal display (LCD), a plasma display, an OLED display, an electrowetting display (EWD), an electro-phoretic display (EPD), an electrochromic display (ECD) or any other applicable display device, which displays image or other visual information from the display side 101.

The optical film 200 includes a transparent substrate 210 having a carrying surface 212 facing the display unit 100, and the material of the transparent substrate 210 may be at least one of polyimide (PI), polycarbonate (PC), polyethersulfone (PES), polyacrylate (PA), polynorbornene (PNB), polyethylene terephthalate (PET), polyetheretherketone (PEEK), polyethylene naphthalate (PEN), polyetherimide (PEI), and glass etc.

A material layer 220 is disposed on the carrying surface 212 of the transparent substrate 210. The material layer 220 can be made of polymer, resin, phtosensitive resin, positive photoresist, negative photoresist, etc. Furthermore, a plurality of truncated tapered units 230 is disposed in the material layer 220, and each of the truncated tapered units 230 has a first end surface 232 nearby the carrying surface 212 and a second end surface 234 away from the carrying face 212. A total internal reflection surface S is foamed between each of the truncated tapered units 230 and the material layer 220 to reflect a light L which is emitted from the display unit 100 and enters the truncated tapered unit 230 through the second end surface 234. The light L reflected by the total internal reflection surface S is adapted to emerge from the truncated tapered unit 230 through the first end surface 232. In the present embodiment, the shape of each of the truncated tapered units 230 may be a cylinder, an elliptic cylinder, a square column, a rectangular column, a rhombus column or irregular columns.

A light absorbing layer 240 is disposed on the carrying surface 212 and located between the transparent substrate 210 and the material layer 220. Herein, the light absorbing layer 240 may be a black matrix, and has a plurality of openings 242, wherein a vertical projection of the openings 242 on the carrying surface 212 overlaps a vertical projection of the first end surfaces 232 of the plurality of truncated tapered units 230 on the carrying surface 212. In other words, the light absorbing layer 240 exposes the first end surfaces 232 of the truncated tapered units 230 for the light L to emerge from the truncated tapered unit 230 through the first end surface 232.

Although an area of the opening 242 of the light absorbing layer 240 is equal to an area of the first end surface 232 of the truncated tapered unit 230 in FIG. 1, the disclosure of the application is not limited thereto. In other embodiments, the area of the opening of the light absorbing layer may be larger than or smaller than an area of the first end surface of the truncated tapered unit.

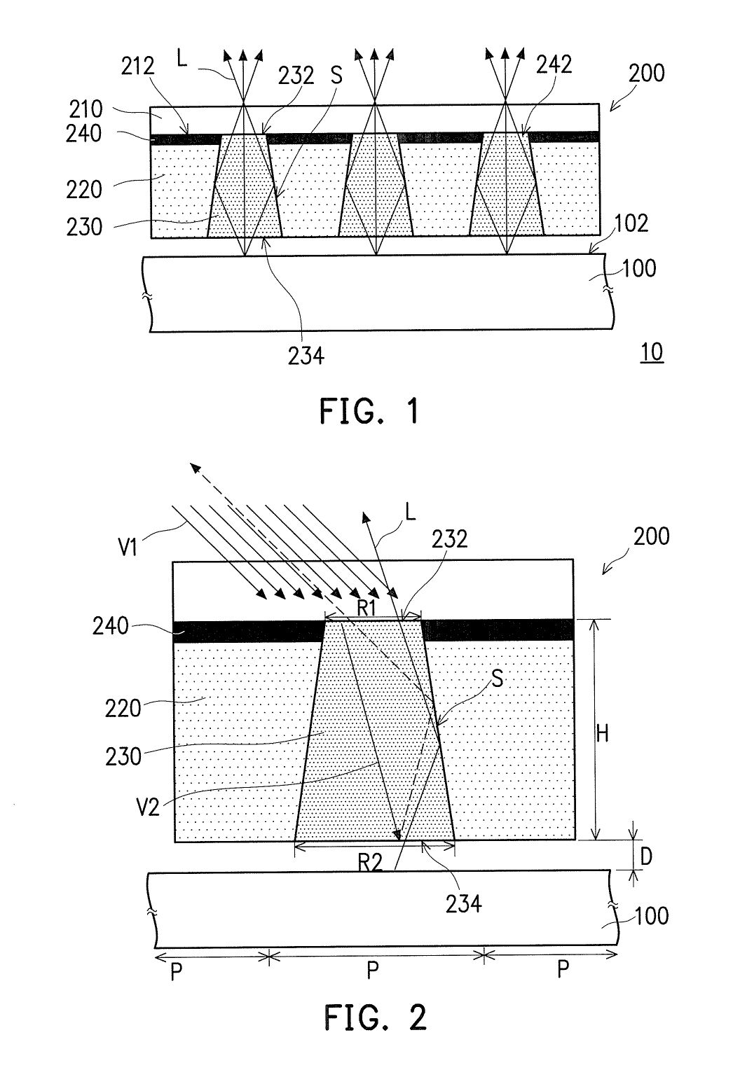

FIG. 2 further shows a partial enlarged view of the display assembly 10 of FIG. 1. Referring to FIG. 1 and FIG. 2, the light L emitted from the display unit 100 can be transmitted through the optical film 200 by the truncated tapered units 230 to maintain high light extraction efficiency of the display unit 100. In addition, a proportion of ambient light V1 irradiated to the optical film 200 is absorbed by the light absorbing layer 240, while other proportion of ambient light V2 incident into the truncated tapered units 230 through their first end surfaces 232 may return by the same path as shown by the dashed line. Therefore, in one of embodiments, being emitted to the optical film 200, only a little proportion of ambient light will be transmitted to the eyes of a user. High visual contrast can be obtained even if the display assembly 10 is placed in an environment with high ambient brightness.

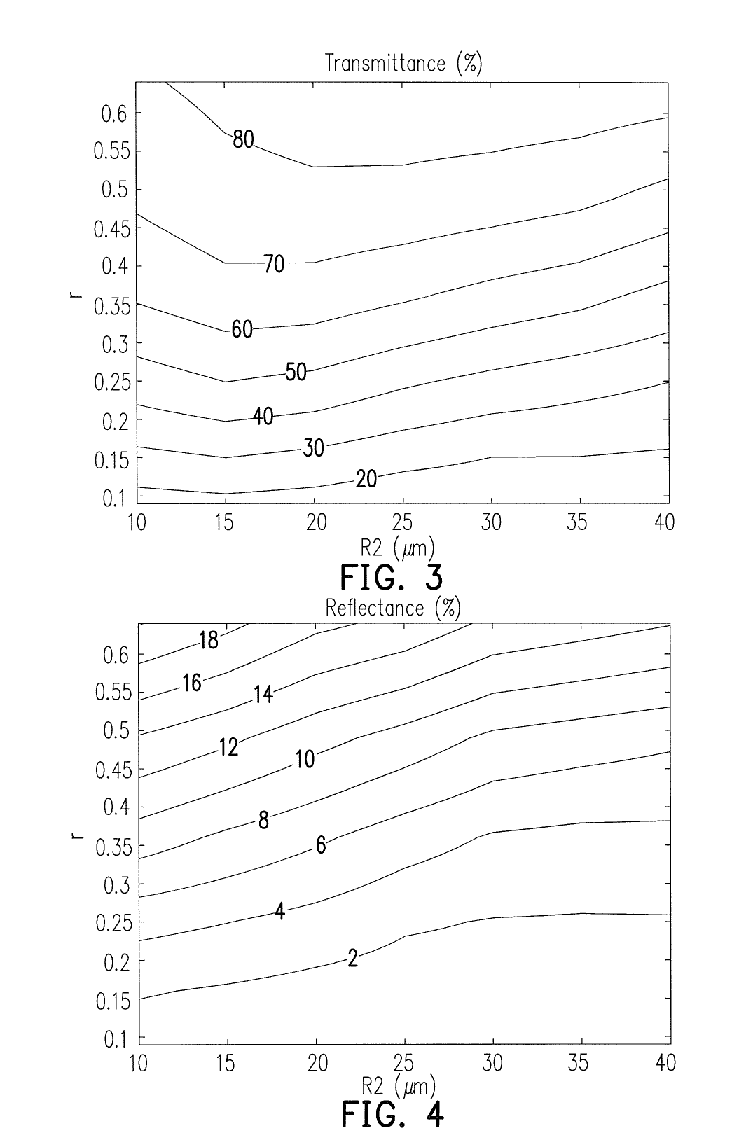

In the present embodiment, the geometry of the truncated tapered units 230 is further defined to achieve favourable light extraction efficiency. Taking a cylindrical truncated tapered unit 230 as a sample, the first end surface 232 and the second end surface 234 are circular and are respectively provided with a diameter R1 and a diameter R2, as shown in FIG. 2. The height of each of the truncated tapered unit 230 is H. FIG. 3 further shows a table illustrating the relationship between the light transmittance and the geometry of the truncated tapered unit. FIG. 4 further shows a table illustrating the relationship between the light reflectance and the geometry of the truncated tapered unit. In the simulation of FIG. 3 and FIG. 4, the height H of the truncated tapered unit 230 is about 20 μm. The X-coordinate refers to the diameter R2, and the Y-coordinate refers to a value r defined as a ratio between an area of the first end surface 232 and an area of the second end surface 234. In practical use, high transmittance is desirable to improve light extraction efficiency, while lower reflectance helps to reduce reflection of ambient light. According to FIG. 3 and FIG. 4, it can be seen that the transmittance may go higher than 40% when r is greater than 0.2, and the reflectance get lower than 18% when r is less than 0.6. Therefore, r may be considered to range from 0.2 to 0.6, and may be further limited from 0.25 to 0.5, or even from 0.35 to 0.45, to meet various practical requirements.

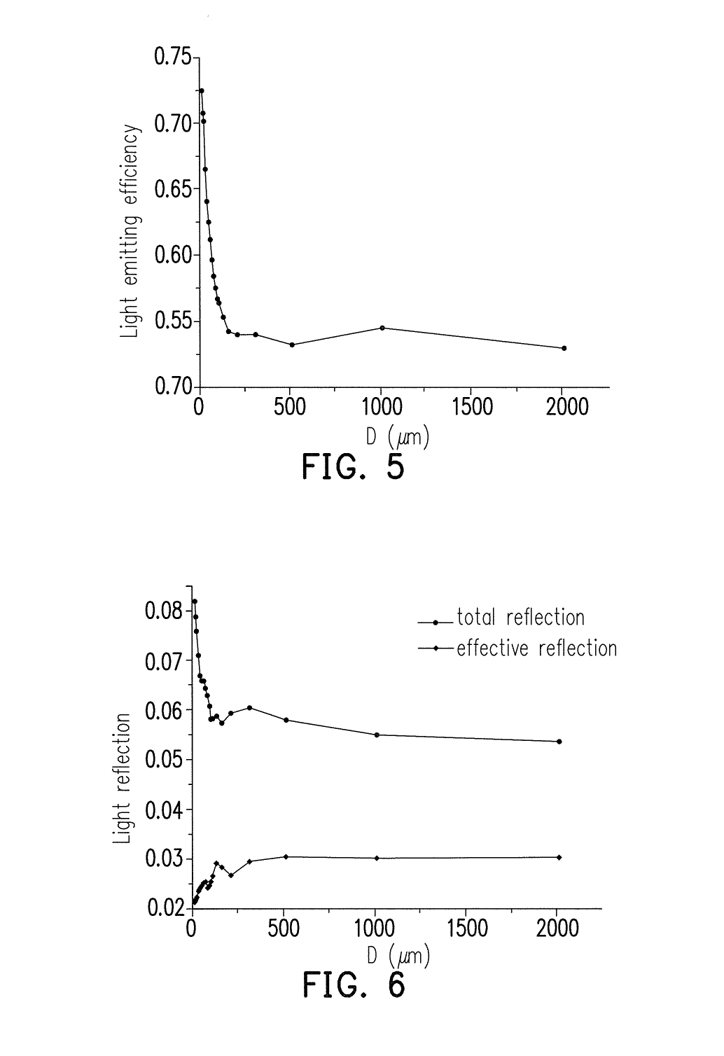

The distance between the optical film 200 and the display unit 100 is D. FIG. 5 shows a table illustrating light extraction efficiency versus the distance D. FIG. 6 shows a table illustrating total reflection and effective reflection versus the distance D. Herein, “total reflection” means sum of reflection of lights in various angles, and “effective reflection” means reflection of lights entering an eye of a user. As shown in FIG. 5 and FIG. 6, when D is greater than 250 μm, the light extraction efficiency goes down, while the total reflection and the effective reflection are kept almost unchanged. Thus, D may be considered to be less than or equal to 250 μm. For example, D may be less than or equal to 100 μm, or less than or equal to 50 μm.

Referring to FIG. 1 again, in this embodiment, the truncated tapered units 230 can be made of photoresist material, such as polymer, resin, photosensitive resin, positive photoresist, negative photoresist, etc., which has a refractive index ranged from 1.3 to 1.9. The material layer 220 as mentioned above has a refractive index ranged from 1.0 to 1.8. The refractive index of each of the truncated tapered units 230 is higher than the refractive index of the material layer 220, and thereby, the total internal reflection surface S can be formed on the interface between each of the truncated tapered units 230 and the material layer 220.

Furthermore, in the case of the display unit 100 comprising a plurality of pixels P, an area of each pixel P is considered to be greater than the area R2 of the second end surface 234 of each of the truncated tapered units 230, such that the accurate alignment process in assembling the display unit 100 and the optical film 200 can be omitted. However, in other embodiments of the disclosure, the area of the second end surface 234 may further be equal to the area of each pixel P, to achieve higher light utilization efficiency.

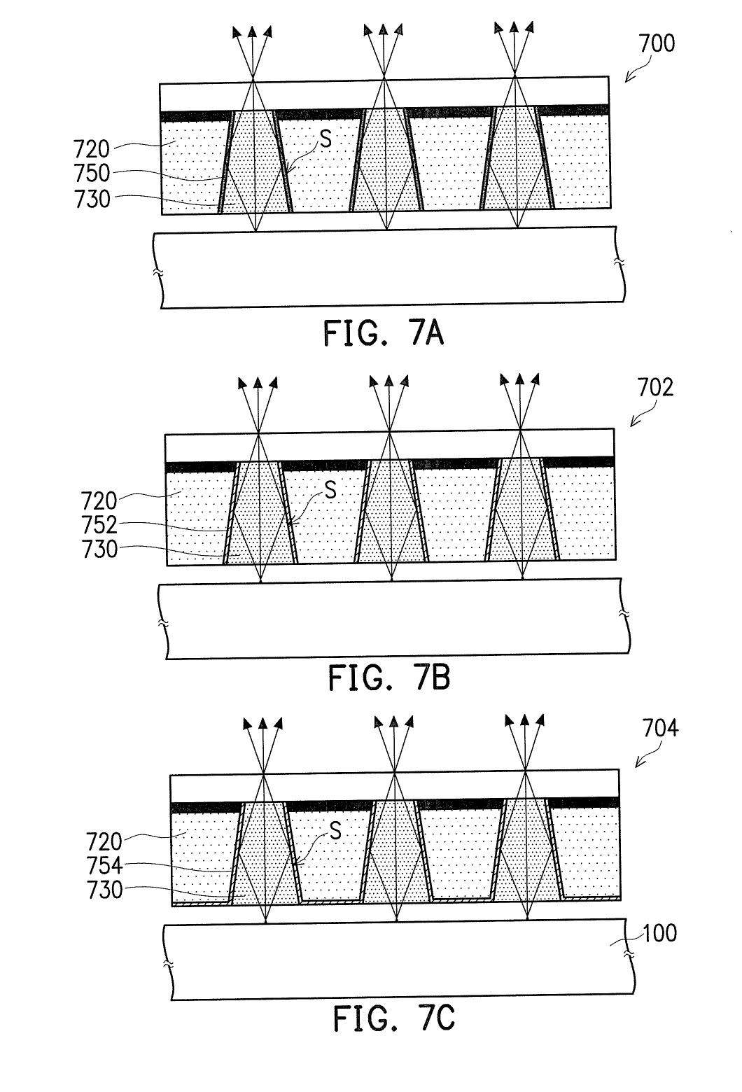

The structure of the optical film or the display assembly with the total internal reflection surface S is not limited to that mentioned in the above embodiment. Display assemblies or optical films of other embodiments are described below with reference of FIG. 7A to FIG. 18. In the following descriptions, differences of the embodiments are mainly described, and the parts with the same technical contents are not repeated.

FIG. 7A illustrates a display assembly according to another embodiment of the present disclosure. In this embodiment, the optical film 700 further comprises a lining layer 750 interlaid between each of the truncated tapered units 730 and the material layer 720. The lining layer 750 can be made of single or multiple dielectric material layers comprising such as silicon oxide (SiOx), silicon nitride (SiNx), indium tin oxide (ITO), zinc oxide (ZnO), etc., which has a refractive index ranged from 1.7 to 2.5. The material layer 720 can be made of photoresist, which has a refractive index ranged from 1.3 to 1.7. The refractive index of the lining layer 750 is higher than the refractive index of the material layer 720, and thereby, the total internal reflection surface S can be formed on the interface between the lining layer 750 and the material layer 720. Due to the existence of the lining layer 750, material selection of the truncated tapered units 730 is more flexible and can be the material having refractive index higher, lower or even equal to that of the material layer 720.

FIG. 7B illustrates a display assembly according to another embodiment of the present disclosure. In this embodiment, the optical film 702 is similar to the optical film 700 of FIG. 7A, except that the material of the lining layer 752 interlaid between each of the truncated tapered units 730 and the material layer 720 is metal, such as aluminium (Al), chrome (Cr), molybdenum (Mo), silver (Ag), or alloy of the aforementioned metal. The lining layer 752 is capable of reflecting light and thereby a reflection surface S is formed on the interface between the lining layer 750 and each of the truncated tapered units 730.

In the previous embodiment, the lining layer 752 is located at the side wall of each of the truncated tapered units 730. However, in further other embodiments, the location of the lining layer may be varied according to practical requirement. FIG. 7C illustrates a display assembly according to another embodiment of the present disclosure.

In this embodiment, the optical film 704 is similar to the optical film 702 of FIG. 7B, except that the lining layer 754 is not only interlaid between each of the truncated tapered units 730 and the material layer 720, but also covering the bottom surface of the material layer 720. Thereby, part of the light emitted from the display unit 100 toward the material layer 720 can be reflected by the lining layer 754 on the bottom surface of the material layer 720, and thus more light can enter the truncated tapered units 730, so as to improve the light extraction efficiency.

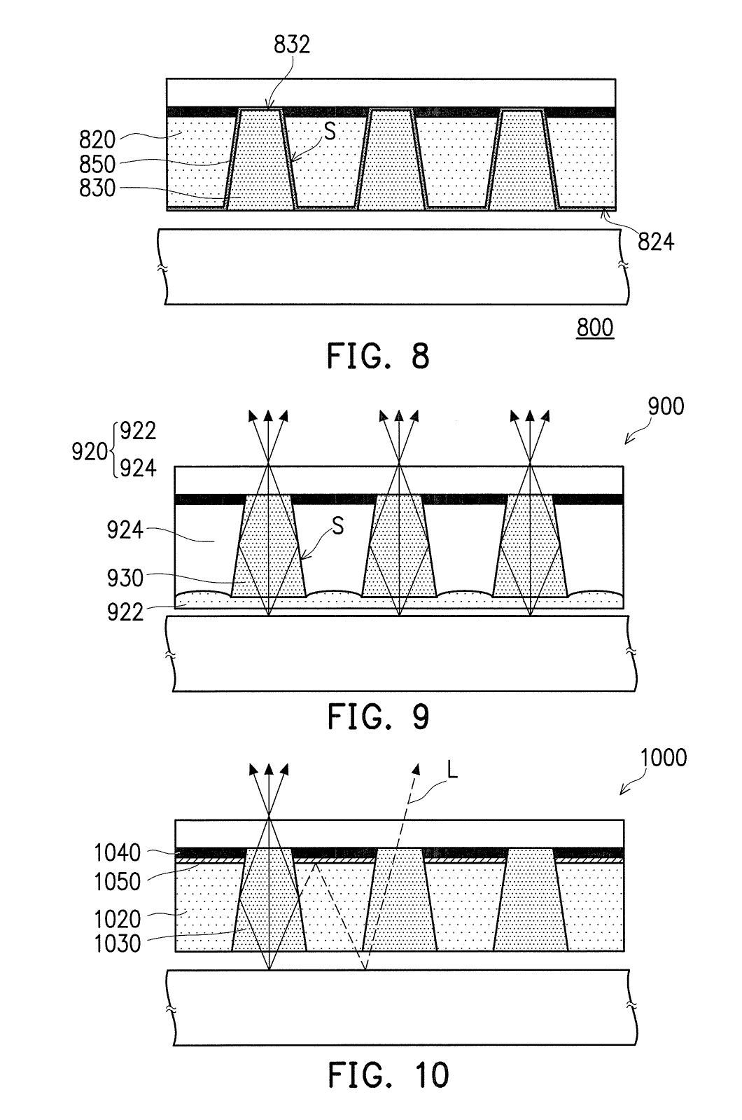

FIG. 8 illustrates a display assembly 800 according to another embodiment of the present disclosure. In this embodiment, the lining layer 850 not only interlaid between each of the truncated tapered units 830 and the material layer 820, but also covers the first end surface 832 of each of the truncated tapered units 830 and the second surface 824 of the material layer 820. The lining layer 850 can be made of single or multiple dielectric material layers comprising such as silicon oxide (SiOx), silicon nitride (SiNx), indium tin oxide (ITO), zinc oxide (ZnO), etc, which has a refractive index ranged from 1.7 to 2.5. The truncated tapered units 830 may be formed by applicable resin materials having a refractive index lower than 1.7 (e.g., from 1.3 to 1.7). And the lining layer 850 may be formed after forming the truncated tapered units 830. The total internal reflection surface S can be formed on the interface between the lining layer 850 and the material layer 820.

FIG. 9 illustrates a display assembly according to another embodiment of the present disclosure. In this embodiment, the material for forming the material layer 920 does not fill the gaps between the truncated tapered units 930 when fabricating the optical film 900. In detail, the material layer 920 includes and air gaps 924 between the truncated tapered units 930 and body portion 922. It is know that the refraction index of air is about 1, and the material of the truncated tapered units 930 (such as photoresist) generally has a higher refraction index, such that the total internal reflection surface S can be formed on the interface between the truncated tapered units 930 and the air gaps 924.

FIG. 10 illustrates a display assembly according to another embodiment of the present disclosure. In this embodiment, a reflective layer 1050 is formed between the light absorbing layer 1040 and the material layer 1020. During the fabrication of the optical film 1000, the reflective layer 1050 and the light absorbing layer 1040 can be patterned with the same mask by conducting only one exposure process to both of the reflective layer 1050 and the light absorbing layer 1040. Alternatively, the reflective layer 1050 and the light absorbing layer 1040 can be patterned with the same mask by conducting different exposure processes to the reflective layer 1050 and the light absorbing layer 1040 individually. Thus, the reflective layer 1050 and the light absorbing layer 1040 are substantially in the same pattern. The material of the reflective layer 1050 comprises metal, such as aluminium (Al), chromium (Cr), molybdenum (Mo), silver (Ag), or alloys including the above materials. Some of the light L can be reflected by the reflective layer 1050 and then transmitted through and emerging from the truncated tapered units 1030, as shown by the dashed line.

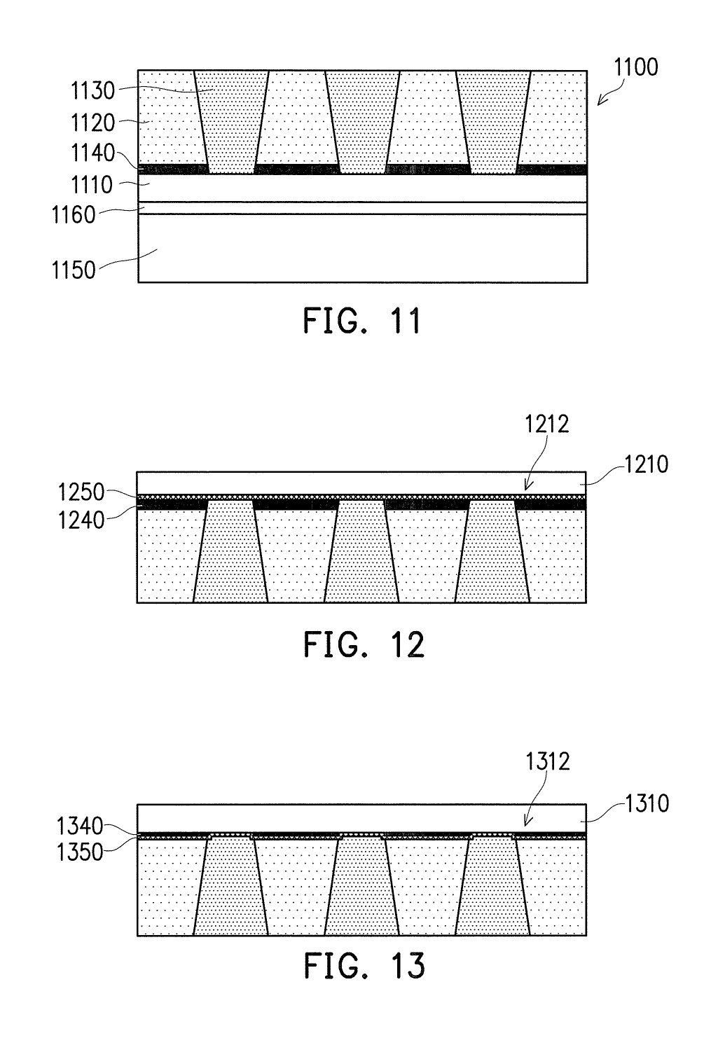

FIG. 11 illustrates an optical film according to another embodiment of the present disclosure. In this embodiment, the optical film 1100 can be fabricated over a carrier 1150, wherein the transparent substrate 1110 is disposed on the carrier 1150 through a de-bonding layer 1160, and then the light absorbing layer 1140, the material layer 1120 and the truncated tapered units 1130 are fowled on the transparent substrate 1110. The carrier 1150 may be a glass substrate or a silicon wafer. And, the carrier 1150 and the de-bonding layer 1160 may be removed after bonding the optical film 1100 to the display unit 100 (as shown in FIG. 1).

In other embodiments, the optical film may be provided with a barrier layer for preventing gas or moisture from entering the optical film or the display assembly. FIG. 12 and FIG. 13 illustrate different optical films according to other embodiments of the present disclosure. As shown in FIG. 12, a barrier layer 1250 is formed over the carrying surface 1212 of the transparent substrate 1210, and the light absorbing layer 1240 is disposed on the barrier layer 1250. And, as shown in FIG. 13, a barrier layer 1350 is formed over the carrying surface 1312 of the transparent substrate 1310 and the light absorbing layer 1340. The barrier layer 1250 or 1350 may comprise an organic layer, an inorganic layer, or an at least two-layered stacked structure formed by interlacing the organic layer and the inorganic layer.

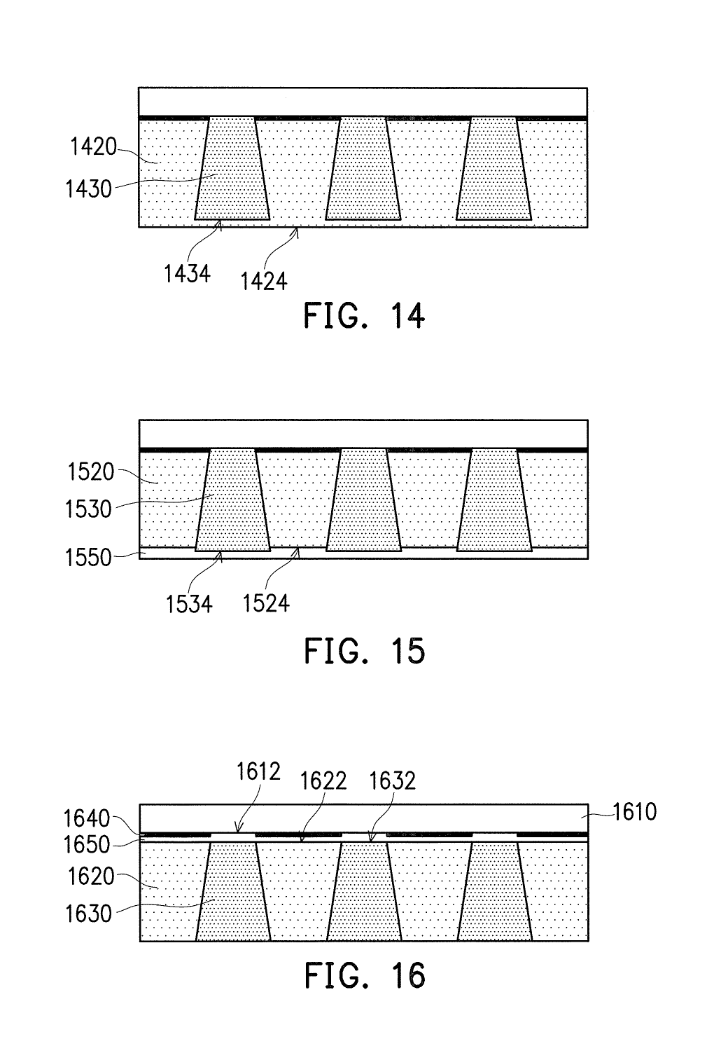

The second end surface of each of the truncated tapered units and the second surface of the material layer may be coplanar as shown in the aforementioned embodiments. Otherwise, the second end surface of each of the truncated tapered units and the second surface of the material layer may further be non-coplanar in other embodiments. FIG. 14 illustrates an optical film according to another embodiment of the present disclosure. Referring to FIG. 14, the second end surface 1434 of each of the truncated tapered units 1430 is covered by the material layer 1420. Thereby, the second surface 1424 of the material layer 1420 can provide a planar surface for the consequent bonding process.

However, the truncated tapered units may protrude from the material after their fabrication process. FIG. 15 illustrates an optical film according to another embodiment of the present disclosure. Referring to FIG. 15, a planarization layer 1550 is fanned to cover the second end surface 1534 of each of the truncated tapered units 1530 and a second surface 1524 of the material layer 1520, so as to provide a planar surface for the consequent bonding process.

FIG. 16 illustrates an optical film according to another embodiment of the present disclosure. In this embodiment, a planarization layer 1650 is formed to cover the carrying surface 1612 of the transparent substrate 1610 and the light absorbing layer 1640 before forming the material layer 1620 and the truncated tapered units 1630. By forming the planarization layer 1650, a planar surface is provided for the following fabrication process of the material layer 1620 and the truncated tapered units 1630, and the formed first end surface 1632 of each of the truncated tapered units 1630 is coplanar with a first surface 1622 of the material layer 1620.

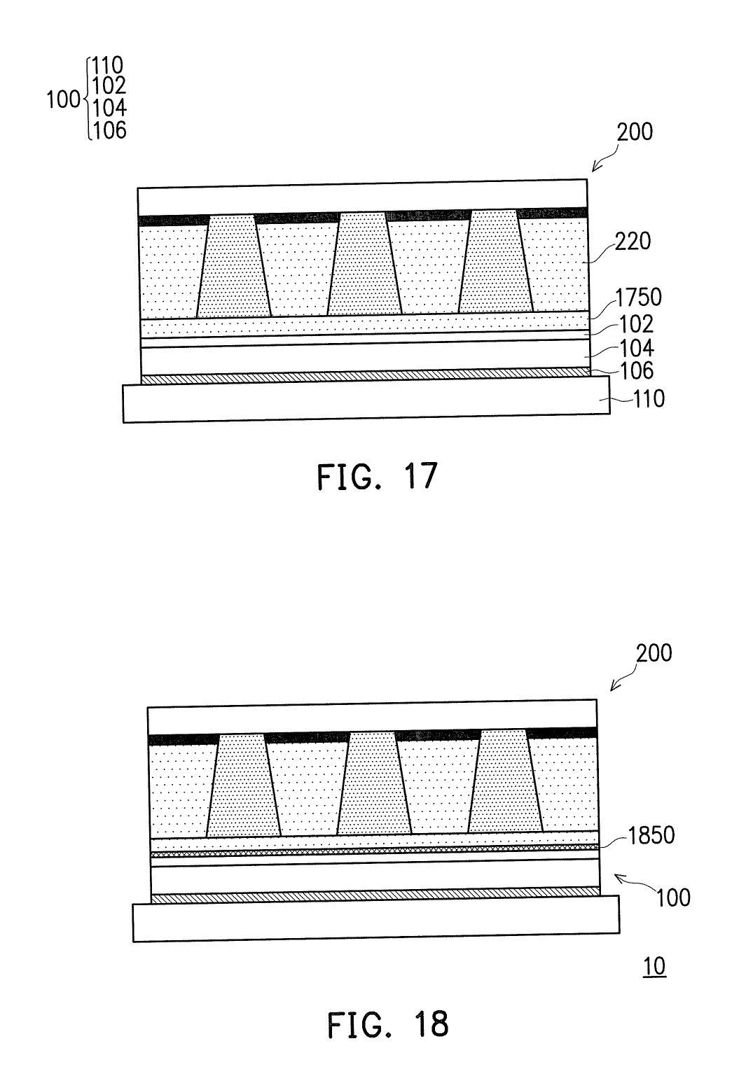

FIG. 17 illustrates a display assembly according to another embodiment of the present disclosure. As shown in FIG. 17, the optical film 200 is bonded to the display unit 100 through an adhesion layer 1750. The display unit 100 of the present embodiment is for example an OLED display, which comprises a substrate 110, a first electrode 102, a second electrode 106 in opposite to the first electrode 102, and a light modulation layer 104 interlaid between the first electrode 102 and the second electrode 106 for emitting the light L (as shown in FIG. 1). The first electrode 102 is disposed nearby the material layer 220, and the second electrode 106 is away from the material layer 220. Herein, the light modulation layer 104 may be a stacked structure of OLED which comprises an electron injection layer, an electron transport layer, an emission layer, a hole transport layer, and a hole injection layer. The material of the adhesion layer 1750 may be acrylic resin or epoxy resin, and can be a pressure sensing adhesion or a filler adhesion. The thickness of the adhesive layer 1750 may be less than or equal to 250 μm. For example, the adhesive layer 1750 may be less than or equal to 100 μm, or less than or equal to 50 μm.

FIG. 18 illustrates a display assembly according to another embodiment of the present disclosure. As shown in FIG. 18, the display assembly 10 of FIG. 18 is similar with that of FIG. 17, except that: a barrier layer 1850 is formed between the display unit 100 and the optical film 200, to preventing gas or moisture from entering the display unit 100 or the optical film 200.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

1. An optical film, comprising:
a transparent substrate, having a carrying surface;
a material layer, disposed on the carrying surface of the transparent substrate;
a plurality of truncated tapered units, disposed in the material layer, and each of the truncated tapered units having a first end surface nearby the carrying surface and a second end surface away from the carrying surface, wherein a ratio of an area of the first end surface and the area of the second end surface is larger than or equal to 0.2 and is less than or equal to 0.6, and a reflection surface is formed between each of the truncated tapered units and the material layer to reflect a light which enters the truncated tapered unit through the second end surface, and the light reflected by the reflection surface is adapted to emerge from the truncated tapered unit through the first end surface; and
a light absorbing layer, disposed on the carrying surface and located between the transparent substrate and the material layer, wherein the light absorbing layer has a plurality of openings, and a vertical projection of the openings on the carrying surface overlaps a vertical projection of the first end surfaces of the plurality of truncated tapered units on the carrying surface.

2. The optical film according to claim 1, further comprising a lining layer interlaid between each of the truncated tapered units and the material layer, wherein a refractive index of the lining layer is higher than a refractive index of the material layer, and a total internal reflection surface is located on an interface between the lining layer and the material layer.

3. The optical film according to claim 1, further comprising a lining layer interlaid between each of the truncated tapered units and the material layer, wherein the lining layer is made of metal, and the reflection surface is located on the interface between the lining layer and each of the truncated tapered units.

4. The optical film according to claim 1, further comprising a reflective layer located between the light absorbing layer and the material layer, wherein the reflective layer and the light absorbing layer are substantially in a same pattern.

5. A display assembly, comprising:
a display unit having a display side;
an optical film disposed on the display side of the display unit, the optical film comprising:
a transparent substrate, having a carrying surface facing the display unit;
a material layer, disposed on the carrying surface of the transparent substrate;
a plurality of truncated tapered units, disposed in the material layer, and each of the truncated tapered units having a first end surface nearby the carrying surface and a second end surface away from the carrying surface, wherein a ratio of an area of the first end surface and the area of the second end surface is larger than or equal to 0.2 and is less than or equal to 0.6, and a reflection surface is formed between each of the truncated tapered units and the material layer to reflect a light which is emitted from the display unit and enters the truncated tapered unit through the second end surface, and the light reflected by the reflection surface is adapted to emerge from the truncated tapered unit through the first end surface; and
a light absorbing layer, disposed on the carrying surface and located between the transparent substrate and the material layer, wherein the light absorbing layer has a plurality of openings, and a vertical projection of the openings on the carrying surface overlaps a vertical projection of the first end surfaces of the plurality of truncated tapered units on the carrying surface.

6. The display assembly according to claim 5, wherein a refractive index of each of the truncated tapered units is higher than a refractive index of the material layer, and the reflection surface is a total internal reflection surface located on an interface between each of the truncated tapered units and the material layer.

7. The display assembly according to claim 5, wherein the optical film further comprises a lining layer interlaid between each of the truncated tapered units and the material layer, a refractive index of the lining layer is higher than a refractive index of the material layer, and a total internal reflection surface is located on the interface between the lining layer and the material layer.

8. The display assembly according to claim 5, wherein the optical film further comprises a lining layer interlaid between each of the truncated tapered units and the material layer, wherein the lining layer is made of metal, and the reflection surface is located on the interface between the lining layer and each of the truncated tapered units.

9. The display assembly according to claim 5, wherein the optical film further comprises a reflective layer located between the light absorbing layer and the material layer, and the reflective layer and the light absorbing layer are substantially in the same pattern.

10. The display assembly according to claim 5, wherein the optical film further comprises a barrier layer covering the carrying surface and disposed between the transparent substrate and the light absorbing layer.

11. The display assembly according to claim 5, wherein the optical film further comprises a barrier layer covering the carrying surface and the light absorbing layer.

12. The display assembly according to claim 5, further comprises an adhesion layer disposed between the display unit and the optical film.

13. The display assembly according to claim 5, further comprises a barrier layer disposed between the display unit and the optical film.

14. The display assembly according to claim 5, wherein the second end surface of each of the truncated tapered units is covered by the material layer.

15. The display assembly according to claim 5, wherein the optical film further comprises a planarization layer covering the carrying surface and the light absorbing layer and providing a planar surface for forming the material layer and the truncated tapered units, wherein the first end surface of each of the truncated tapered units is coplanar with a first surface of the material layer.

16. The display assembly according to claim 5, wherein the optical film further comprises a planarization layer covering the second end surface of each of the truncated tapered units and a second surface of the material layer.

17. The display assembly according to claim 5, wherein the display unit comprises a plurality of pixels, and an area of each pixel is greater than the area of the second end surface of each of the truncated tapered units.

18. The display assembly according to claim 5, wherein the display unit comprises:
a first electrode, nearby the material layer;
a second electrode, away from the material layer; and
a light modulation layer interlaid between the first electrode and the second electrode for emitting the light.

19. The display assembly according to claim 18, wherein a distance between the display unit and the optical film is less than or equal to 250 μm.

20. The display assembly according to claim 5, wherein the ratio of the area of the first end surface and the area of the second end surface is larger than or equal to 0.25 and is less than or equal to 0.5.
